(19) United States
(12) Patent Application Publication
(10) Pub. No.: US 2024/0006847 A1
(43) Pub. Date: Jan. 4, 2024

(54) LASER APPARATUS AND LASER APPARATUS CONTROL METHOD

(71) Applicant: FURUKAWA ELECTRIC CO., LTD., Tokyo (JP)

(72) Inventors: Akihisa KONDO, Tokyo (JP); Masayoshi KIMURA, Tokyo (JP); Jun MIURA, Tokyo (JP); Masayoshi NISHITA, Tokyo (JP)

(73) Assignee: FURUKAWA ELECTRIC CO., LTD., Tokyo (JP)

(21) Appl. No.: 18/465,228

(22) Filed: Sep. 12, 2023

Related U.S. Application Data
(63) Continuation of application No. PCT/JP2021/014966, filed on Apr. 8, 2021.

(51) Int. Cl. H01S 5/0687; H01S 5/0683

(52) U.S. Cl. CPC H01S 5/0687; H01S 5/06837

(57) ABSTRACT

A laser apparatus includes: a laser unit including a light source unit configured to change a frequency of laser light to be output; and a monitor unit configured to acquire a monitor value corresponding to a frequency equivalent amount corresponding to the frequency of the laser light; and a control unit configured to control the frequency of the laser light by supplying a control amount to the laser unit. The monitor unit at least includes: a first frequency filter and a second frequency filter; a first detection unit; and a second detection unit. The control unit is configured to acquire a target frequency, acquire a first ratio and a second ratio, set, as a monitor value corresponding to the frequency of the laser light, one of the first ratio, the second ratio, a third ratio, acquire a target value, and control the control amount.

This application is a continuation of International Application No. PCT/JP2021/014966, filed on Apr. 8, 2021, the entire contents of which are incorporated herein by reference.

### BACKGROUND

This disclosure relates to a laser apparatus and a laser apparatus control method.

A technique that, in a laser apparatus that is able to change a frequency of laser light to be output, controls a frequency of laser light by using two or more frequency filters each having a transmission characteristic such that transmittance periodically varies with respect to a frequency of input light has been disclosed (Japanese Laid-open Patent Publication No. 2019-140304). The two or more frequency filters are designed such that respective phases are shifted from one another. In the control as described above, light that has transmitted through a frequency filter for which a change of transmittance with respect to a frequency change at a control target frequency of the laser light is larger is used for the control.

### SUMMARY

In the frequency filter with the transmission characteristic that periodically varies with respect to the frequency, a change of transmittance with respect to a frequency change is reduced in a frequency band that is close to an extreme value of the subject transmission characteristic, and control accuracy is reduced. The frequency band as described above is also referred to as a dead zone.

In the technique disclosed in Japanese Laid-open Patent Publication No. 2019-140304, the two or more frequency filters are set such that the respective phases are shifted from one another and a frequency filter that does not included in the dead zone at the control target frequency is selected, so that it may be possible to prevent reduction in control accuracy.

However, even with use of the technique disclosed in Japanese Laid-open Patent Publication No. 2019-140304, if the transmission characteristic of the frequency filter is shifted in a frequency axis direction due to an unintentional cause, that is, if what is called a lateral shift occurs, the control target frequency may unintentionally overlap with the dead zone of the selected frequency filter. Accordingly, the control accuracy may be reduced. The unintentional cause as described above may include temperature variation or a temporal change of the frequency filter.

There is a need for a laser apparatus and a laser apparatus control method that are able to prevent reduction in control accuracy of the frequency of the laser light

According to one aspect of the present disclosure, there is provided a laser apparatus including: a laser unit including a light source unit configured to change a frequency of laser light to be output; and a monitor unit configured to acquire a monitor value corresponding to a frequency equivalent amount corresponding to the frequency of the laser light; and a control unit configured to control the frequency of the laser light by supplying a control amount to the laser unit, wherein the monitor unit at least includes: a first frequency filter and a second frequency filter that have transmission characteristics such that transmittance periodically varies with respect to a frequency of input light and phases are shifted relative to each other; a first detection unit configured to detect first intensity corresponding to intensity of the laser light transmitted through the first frequency filter; and a second detection unit configured to detect second intensity corresponding to intensity of the laser light transmitted through the second frequency filter, and the control unit is configured to acquire a target frequency that is a control target of the frequency of the laser light, acquire a first ratio corresponding to a ratio of the first intensity to intensity of the laser light and a second ratio corresponding to a ratio of the second intensity to the intensity of the laser light, set, as a monitor value corresponding to the frequency of the laser light, one of the first ratio, the second ratio, a third ratio that is a sum of the first ratio and the second ratio, and a fourth ratio that is a difference between the first ratio and the second ratio, acquire a target value corresponding to the target frequency based on one of the first to the fourth ratios, and control the control amount such that an absolute value of a difference between the target value and the monitor value is reduced.

According to another aspect of the present disclosure, there is provided a laser apparatus control method implemented by a laser apparatus including a light source unit configured to change a frequency of laser light to be output, the laser apparatus control method including: acquiring a target frequency as a control target of the frequency of the laser light; detecting intensity of the laser light by detecting first intensity corresponding to intensity of the laser light transmitted through a first frequency filter, the first frequency filter having a transmission characteristic such that transmittance periodically varies with respect to a frequency of input light and a phase is shifted relative to a second frequency filter that has a transmission characteristic such that transmittance periodically varies with respect to the frequency of the input light, and detecting second intensity corresponding to intensity of the laser light transmitted through the second frequency filter; acquiring a first ratio corresponding to a ratio of the first intensity to the intensity of the laser light and a second ratio corresponding to a ratio of the second intensity to the intensity of the laser light; setting a monitor value corresponding to a frequency equivalent amount corresponding to the frequency of the laser light from among the first ratio, the second ratio, a third ratio that is a sum of the first ratio and the second ratio, and a fourth ratio that is a difference between the first ratio and the second ratio; acquiring a target value corresponding to the target frequency based on one of the first to the fourth ratios; and adjusting a control amount such that an absolute value of a difference between the target value and the monitor value is reduced.

### BRIEF DESCRIPTION OF THE DRAWINGS

FIG. 1 is a diagram illustrating a configuration of a laser apparatus according to a first embodiment;

FIG. 2 is a diagram illustrating a configuration of a light source unit;

FIG. 3 is a block diagram illustrating a configuration of a control unit according to the first embodiment;

FIG. 4 is a diagram illustrating frequency discrimination curves;

FIG. 5 is a diagram for explaining a margin;

FIG. 6 is a diagram illustrating a relationship between φ and the margin;

FIG. 7 is a diagram illustrating temperature-dependent changes of frequency discrimination curves according to a comparative example;

FIG. 8 is a diagram illustrating temperature-dependent changes of the frequency discrimination curves according to the embodiment;

FIG. 9 is a flowchart illustrating a control method performed by the control unit according to the first embodiment;

FIG. 10 is a flowchart illustrating a control method in which correction is performed in accordance with environmental temperature;

FIG. 11 is a flowchart illustrating a control method in a laser apparatus according to a fourth modification;

FIG. 12 is a flowchart illustrating another example of the control method in the laser apparatus according to the fourth modification;

FIG. 13 is a flowchart illustrating a part of a control method in a laser apparatus of another modification of the fourth modification; and

FIG. 14 is a flowchart illustrating a part of a control method in a laser apparatus of still another modification of the fourth modification.

### DETAILED DESCRIPTION

Modes (hereinafter, embodiments) for carrying out the present disclosure will be described below with reference to the drawings. The present disclosure is not limited by the embodiments described below. Further, in description of the drawings, the same components are appropriately denoted by the same reference symbols. Furthermore, it is necessary to note that the drawings are schematic, and a relation between a thickness and a width of each of the components, ratios among the components, and the like may be different from actual ones. Moreover, the drawings may include a portion that has different dimensional relations or ratios. Furthermore, in the drawings, xyz coordinate axes are appropriately illustrated and directions are explained with use of the xyz coordinate axes.

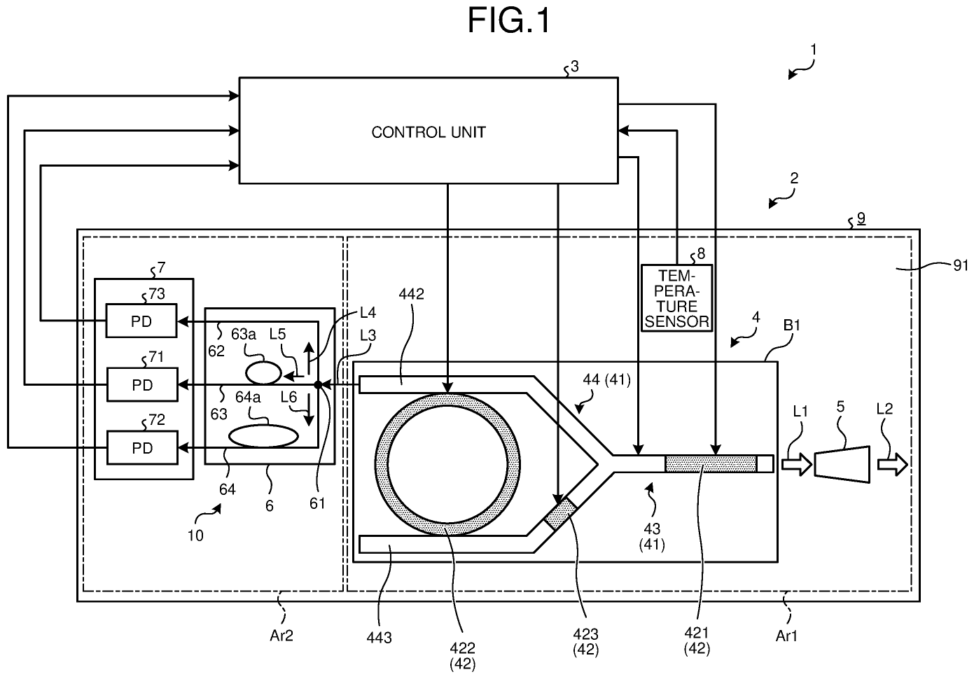

FIG. 1 is a diagram illustrating a configuration of a laser apparatus according to a first embodiment.

A laser apparatus 1 includes a laser unit 2 that is modularized, and a control unit 3 that performs control steps for controlling operation of the laser unit 2.

Meanwhile, the laser unit 2 and the control unit 3 are configured as separate units in FIG. 1, but may be modularized in an integrated manner.

The laser unit 2 is able to change a frequency of laser light to be output to a certain frequency among a plurality of frequencies and outputs the laser light with the changed frequency, under the control of the control unit 3. The laser unit 2 includes a light source unit 4, a semiconductor optical amplifier (SOA) 5, a planar lightwave circuit (PLC) 6, a light detection unit 7, a temperature sensor 8, and a temperature controller 9. The planar lightwave circuit and the light detection unit 7 constitute a monitor unit 10.

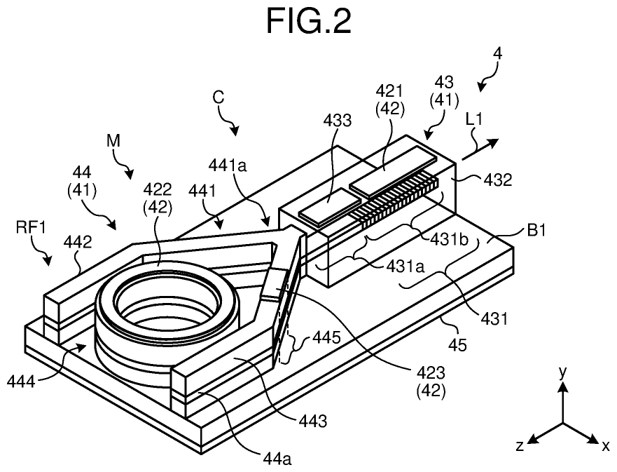

FIG. 2 is a diagram illustrating a configuration of the light source unit.

The light source unit 4 is, for example, laser using the Vernier effect, and outputs laser light L1 under the control of the control unit 3. The light source unit 4 includes a laser main body unit 41 that is able to change a frequency of the laser light L1 to be output, and a change unit 42. The change unit 42 includes three microheaters that generate heat in accordance with electric power supplied from the control unit 3, and locally heats the laser main body unit 41 to change the frequency of the laser light L1 that is output from the laser main body unit 41.

The laser main body unit 41 includes a first waveguide unit 43 and a second waveguide unit 44, each of which is formed on a common base portion B1. Here, the base portion B1 is formed of, for example, an n-type InP. Further, on a back surface of the base portion B1, for example, an n-side electrode 45 that includes AuGeNi and that comes in ohmic contact with the base portion B1 is formed.

The first waveguide unit 43 has an embedded waveguide structure. The first waveguide unit 43 includes a waveguide unit 431, a semiconductor lamination unit 432, and a p-side electrode 433.

The waveguide unit 431 is formed so as to be elongated in a z direction in the semiconductor lamination unit 432.

Further, in the first waveguide unit 43, a gain unit 431a and a Distributed Bragg Reflector (DBR) type diffraction grating layer 431b are arranged.

Here, the gain unit 431a is an active layer that has a multiple quantum well structure made pf InGaAsP and that includes an optical confinement layer. Further, the diffraction grating layer 431b is configured with a sampling diffraction grating that is made of InGaAsP and InP.

The semiconductor lamination unit 432 is configured by laminating InP-based semiconductor layers, and has a function as a cladding portion with respect to the waveguide unit 431, for example.

The p-side electrode 433 is arranged so as to extend along the gain unit 431a on the semiconductor lamination unit 432. Meanwhile, an SiN protective film (not illustrated) is formed on the semiconductor lamination unit 432. Further, the p-side electrode 433 comes into contact with the semiconductor lamination unit 432 via an opening (not illustrated) that is formed in the SiN protective film.

Here, a DBR heater 421 that is a microheater is arranged so as to extend along the diffraction grating layer 431b on the SiN protective film of the semiconductor lamination unit 432. Further, the DBR heater 421 generates heat in accordance with electric power supplied from the control unit 3, and heats the diffraction grating layer 431b. Furthermore, the control unit 3 controls the electric power that is supplied to the DBR heater 421, so that temperature of the diffraction grating layer 431b is changed and a refractive index of the diffraction grating layer 431b is changed.

The second waveguide unit 44 includes a bifurcation unit 441, two arm portions 442 and 443, and a ring-shaped waveguide 444.

The bifurcation unit 441 is configured as a 1×2-type branching waveguide that includes a 1×2-type multimode interference (MMI)-type waveguide 441a such that two ports are connected to the two respective arm portions 442 and 443 and one port is connected to the first waveguide unit 43. In other words, the bifurcation unit 441 integrates one ends of the two arm portions 442 and 443, and the two arm portions 442 and 443 are optically coupled with the diffraction grating layer 431b.

The arm portions 442 and 443 are extended in the z direction and arranged so as to sandwich the ring-shaped waveguide 444. The arm portions 442 and 443 are optically coupled with the ring-shaped waveguide 444 at a same coupling coefficient K as that of the ring-shaped waveguide 444. A value of K is, for example, 0.2. Further, the arm portions 442 and 443 and the ring-shaped waveguide 444 constitute a ring resonator filter RF1. Furthermore, the ring resonator filter RF1 and the bifurcation unit 441 constitute a reflecting mirror M.

Here, a RING heater 422 that is a microheater has a ring shape and is arranged on an SiN protective layer (not illustrated) that is formed so as to cover the ring-shaped waveguide 444. Further, the RING heater 422 generates heat in accordance with electric power supplied from the control unit 3 and heats the ring-shaped waveguide 444. Furthermore, the control unit 3 controls the electric power that is supplied to the RING heater 422, so that temperature of the ring-shaped waveguide 444 is changed and a refractive index of the ring-shaped waveguide 444 is changed.

Each of the bifurcation unit 441, the arm portions 442 and 443, and the ring-shaped waveguide 444 as described above has a high-mesa waveguide structure in which an optical waveguide layer 44a that is made of InGaAsP is sandwiched between cladding layers that are made of InP.

Here, a Phase heater 423 that is a microheater is arranged on a part of an SiN protective layer (not illustrated) of the arm portion 443. A certain region of the arm portion 443 below the Phase heater 423 functions as a phase adjustment unit 445 that changes a phase of light. Further, the Phase heater 423 generates heat in accordance with electric power supplied from the control unit 3 and heats the phase adjustment unit 445. Furthermore, the control unit 3 controls the electric power that is supplied to the Phase heater 423, so that temperature of the phase adjustment unit 445 is changed and a refractive index of the phase adjustment unit 445 is changed.

The first waveguide unit 43 and the second waveguide unit 44 as described above constitute an optical resonator C that includes the diffraction grating layer 431b and the reflecting mirror M that are optically coupled with each other. Further, the gain unit 431a and the phase adjustment unit 445 are arranged inside the optical resonator C.

The diffraction grating layer 431b generates a first comb-like reflection spectrum with periodic reflection characteristics at predetermined frequency intervals. In contrast, the ring resonator filter RF1 generates a second comb-like reflection spectrum with periodic reflection characteristics at predetermined frequency intervals.

Here, the second comb-like reflection spectrum has a peak with a narrower full width at half maximum than a full width at half maximum of a peak of the first comb-like reflection spectrum, and has the periodic reflection characteristics at a frequency interval different from a frequency interval of the first comb-like reflection spectrum.

As an example of the characteristics of each of the comb-like reflection spectrums, a frequency interval (free spectrum range (FSR)) between peaks of the first comb-like reflection spectrum is 373 GHz. Further, the full width at half maximum of each of the peaks is 43 GHz. In contrast, a frequency interval (FSR) between peaks of the second comb-like reflection spectrum is 400 GHz. Furthermore, the full width at half maximum of each of the peaks is 25 GHz. In other words, the full width at half maximum (25 GHz) of each of the peaks of the second comb-like reflection spectrum is narrower than the full width at half maximum (43 GHz) of each of the peaks of the first comb-like reflection spectrum.

The light source unit 4 is configured such that one of the peaks of the first comb-like reflection spectrum and one of the peaks of the second comb-like reflection spectrum may overlap with each other on a frequency axis to realize laser oscillation. The overlapping as described above is realized by performing, with use of at least one of the DBR heater 421 and the RING heater 422, at least one of the followings, that is, by entirely moving and changing the first comb-like reflection spectrum on the frequency axis by causing the DBR heater 421 to heat the diffraction grating layer 431b and changing a refractive index of the diffraction grating layer 431b due to a thermo-optic effect or by entirely moving and changing the second comb-like reflection spectrum on the frequency axis by causing the RING heater 422 to heat the ring-shaped waveguide 444 and changing a refractive index of the ring-shaped waveguide 444.

In contrast, the light source unit 4 has a resonator mode by the optical resonator C. Further, in the light source unit 4, a cavity length of the optical resonator C is set such that a resonator mode interval (longitudinal mode interval) becomes equal to or smaller than 25 GHz. With this setting, the cavity length of the optical resonator C is equal to or larger than 1800 micrometers (μm), so that it is possible to expect reduction of a linewidth of laser light that oscillates. Meanwhile, it is possible to make minor adjustment to a frequency of the optical resonator C in the resonator mode by entirely moving the frequency in the resonator mode on the frequency axis by causing the Phase heater 423 to heat the phase adjustment unit 445 and changing a refractive index of the phase adjustment unit 445. In other words, the phase adjustment unit 445 is a part that actively changes an optical path length of the optical resonator C.

The light source unit 4 is configured such that, when the control unit 3 causes an electric current to flow from the n-side electrode 45 and the p-side electrode 433 to the gain unit 431a and when the gain unit 431a emits light, laser oscillation occurs at a certain frequency, such as 193.4 THz, at which a peak of a spectrum component of the first comb-like reflection spectrum, a peak of a spectrum component of the second comb-like reflection spectrum, and one of the resonator modes of the optical resonator C match with one another, and the laser light L1 is output.

The light source unit 4 is able to change the frequency of the laser light L1 by using the Vernier effect. In other words, if the DBR heater 421 is controlled by adjusting the electric power that is supplied from the control unit 3, a comb-like reflection spectrum of the DBR heater 421 is shifted on the frequency axis. Similarly, if the RING heater 422 is controlled, a comb-like reflection spectrum of the RING heater 422 is shifted on the frequency axis. Similarly, if the Phase heater 423 is controlled, a spectrum of the Phase heater 423 is shifted on the frequency axis.

For example, first, a certain state is made in which laser oscillates at a frequency f1 at which a reflection peak of the DBR, the resonator mode of the optical resonator C, and a reflection peak of the RING match with one another. To realize the state as described above, for each of the DBR heater 421 and the RING heater 422, a frequency position at which the reflection spectrum of each of the DBR and the RING reaches a peak is set based on the electric power to be supplied. Further, for the Phase heater 423, a frequency position at which the resonator mode reaches a peak is set based on the electric power to be supplied. Assuming that a frequency at which the reflection peak of the DBR, the resonator mode of the optical resonator C, and the reflection peak of the RING match with one another from the state in which laser oscillates at the frequency f1 is referred to as a frequency f2, it is possible to adjust the frequency of the laser light L1 to the frequency f2. Meanwhile, it is possible to control the electric power to be supplied to each of the heaters by adopting an electric current as a control amount. In other words, the control unit 3 controls the frequency of the laser light L1 by supplying electric power corresponding to the electric current adopted as the control amount to the light source unit 4.

When the frequency of the laser light L1 is to be changed from the first frequency to the second frequency, for example, the DBR heater 421 and the RING heater 422 are subjected to feed-forward control such that the comb-like reflection spectrums of the DBR and the RING overlap with each other at the second frequency, and thereafter, the Phase heater 423 is subjected to feedback control such that any one of the resonator modes matches the second frequency. However, a control method is not limited to the above.

Referring back to FIG. 1, explanation will be continued. The semiconductor optical amplifier 5 has an embedded waveguide structure that includes an active core layer that is made of the same material and that has the same structure as those of the first waveguide unit 43, although specific illustration is omitted. However, the diffraction grating layer 431b is not arranged. The semiconductor optical amplifier 5 is optically coupled with the light source unit 4 by a spatial coupling optical system (not illustrated). Further, the laser light L1 that is output from the light source unit 4 is input to the semiconductor optical amplifier 5. The semiconductor optical amplifier 5, if an electric current is supplied from the control unit 3, amplifies the laser light L1 and outputs the amplified laser light as laser light L2. Meanwhile, the semiconductor optical amplifier 5 may be constructed on the base portion B1 in a monolithic manner with respect to the light source unit 4.

The planar lightwave circuit 6 is optically coupled with the arm portion 442 by a spatial coupling optical system (not illustrated). Further, similarly to the laser light L1, a part of laser light L3 that is generated by laser oscillation in the light source unit 4 is input to the planar lightwave circuit 6 via the arm portion 442. Meanwhile, the laser light L3 has the same frequency as the frequency of the laser light L1, and has certain intensity that corresponds to intensity of the laser light L1. The planar lightwave circuit 6 includes a light splitting unit 61, an optical waveguide 62, an optical waveguide 63 that includes a frequency filter 63a as a ring resonator type optical filter, and an optical waveguide 64 that includes a frequency filter 64a as a ring resonator type optical filter. The frequency filter 63a is one example of a first frequency filter and the frequency filter 64a is one example of a second frequency filter.

The light splitting unit 61 spits the input laser light L3 into three beams of laser light L4, L5, and L6. The optical waveguide 62 guides the laser light L4 to a Photo Diode (PD) 73 (to be described later) in the light detection unit 7. The optical waveguide 63 guides the laser light L5 to a PD 71 (to be described later) in the light detection unit 7. The optical waveguide 64 guides the laser light L6 to a PD 72 (to be described later) in the light detection unit 7.

Here, the frequency filter 63a has a transmission characteristic such that transmittance periodically varies with respect to a frequency of input light, and transmits the laser light L5 at transmittance that corresponds to a frequency of the laser light L5. Further, the laser light L5 that has transmitted through the frequency filter 63a enters the PD 71. In other words, the frequency filter 63a is a waveguide-type frequency filter. Meanwhile, it may be possible to use, as the frequency filter 63a, an etalon filter or a Mach-Zehnder Interferometer (MZI) filter that has periodic transmission characteristics with respect to the frequency of input light.

Similarly, the frequency filter 64a has a transmission characteristic such that transmittance periodically varies with respect to a frequency of input light, and transmits the laser light L6 at transmittance that corresponds to a frequency of the laser light L6. Further, the laser light L6 that has transmitted through the frequency filter 64a enters the PD 72. It may be possible to use, as the frequency filter 64a, an etalon filter or an MZI filter that has periodic transmission characteristics with respect to the frequency of input light.

It is preferable that the transmission characteristics of the frequency filters 63a and 64a have the same cycles. Further, as will be described later, the transmission characteristics of the frequency filters 63a and 64a are set such that phases are relatively shifted from each other.

The light detection unit 7 includes the PDs 71, 72, and 73 and performs a detection step. The PD 73 receives the laser light L4 (which has the same frequency as the laser light L1 that is output from the light source unit 4 and has intensity that corresponds to the intensity of the laser light L1), and outputs an electrical signal that corresponds to the intensity of the laser light L4 to the control unit 3. The PD 71 receives the laser light L5 that has transmitted through the frequency filter 63a, and outputs an electrical signal that corresponds to the intensity of the laser light L5 to the control unit 3. The PD 72 receives the laser light L6 that has transmitted through the frequency filter 64a, and outputs an electrical signal that corresponds to the intensity of the laser light L6 to the control unit 3. Furthermore, the electrical signal that is output from each of the PDs 71, 72, and 73 is used for frequency lock control that is performed by the control unit 3 (control for adjusting the frequency of the laser light L1 output from the light source unit 4 to a target frequency).

The PD 71 is one example of a first detection unit that detects first intensity that is the intensity of the laser light L5, which corresponds to the intensity of the laser light L1 that has transmitted through the frequency filter 63a. The PD 72 is one example of a second detection unit that detects second intensity that is the intensity of the laser light L6, which corresponds to the intensity of the laser light L1 that has transmitted through the frequency filter 64a. The PD 73 is one example of a third detection unit that detects third intensity that is the intensity of the laser light L4, which corresponds to the intensity of the laser light L1.

The temperature sensor 8 is configured with, for example, a thermistor or the like, is mounted on a mounting surface 91 of the temperature controller 9, and detects ambient temperature of the light source unit 4 and the planar lightwave circuit 6. Meanwhile, the temperature sensor 8 may be arranged on the outside of the temperature controller 9 and may detect, as the ambient temperature, temperature of an environment in which the laser apparatus 1 is arranged. The temperature sensor 8 outputs an electrical signal that includes information on the detected temperature to the control unit 3.

The temperature controller 9 is configured with, for example, a Thermo Electric Cooler (TEC) including a Peltier element, or the like. The light source unit 4, the semiconductor optical amplifier 5, the planar lightwave circuit 6, the light detection unit 7, and the temperature sensor 8 are mounted on the temperature controller 9. Further, the temperature controller 9 controls temperature of each of the light source unit 4, the semiconductor optical amplifier 5, the planar lightwave circuit 6, the light detection unit 7, and the temperature sensor 8 in accordance with supplied electric power. In this case, the control unit 3 controls electric power that is supplied to the temperature controller 9 such that the light source unit 4 mainly maintains constant temperature, on the basis of the information on the temperature detected by the temperature sensor 8. It is preferable to perform control such that the light source unit 4 mainly maintains constant temperature in order to prevent variation of the frequency of the laser light L1 that depends on operating conditions and external environmental temperature.

Meanwhile, if the temperature controller 9 is configured such that the mounting surface 91 on which the light source unit 4, the semiconductor optical amplifier 5, the planar lightwave circuit 6, the light detection unit 7, and the temperature sensor 8 are mounted is divided into two areas such as a first area Ar1 in which the light source unit 4 and the semiconductor optical amplifier 5 are mounted and a second area Ar2 in which the planar lightwave circuit 6 and the light detection unit 7 are mounted, the temperature sensor 8 may be mounted in the first area Ar1. In this case, the temperature sensor 8 may be arranged in the vicinity of the light source unit 4 or may be mounted on the light source unit 4. Further, the temperature sensor 8 may be mounted in the second area Ar2 and may be arranged in the vicinity of the planar lightwave circuit 6.

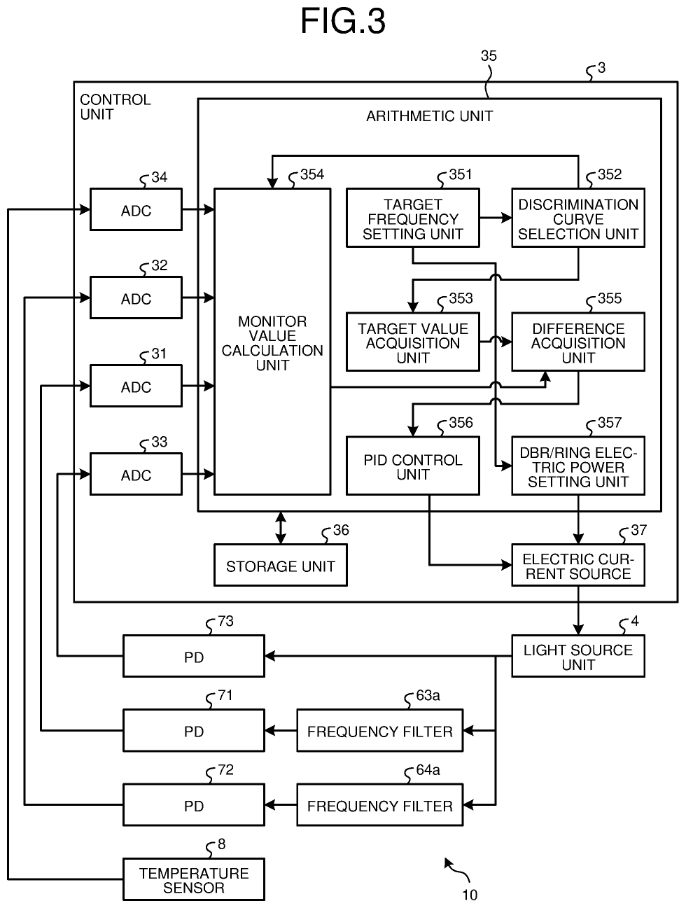

A configuration of the control unit 3 will be described below. FIG. 3 is a block diagram illustrating the configuration of the control unit. The control unit 3 is connected to, for example, a higher-level control apparatus (not illustrated) that includes a user interface or the like, and controls operation of the light source unit 4 in accordance with an instruction that is given by a user via the higher-level control apparatus.

Meanwhile, in the following, frequency lock control that is performed by the control unit 3 as a main part of the present disclosure will be mainly described. Further, FIG. 3 mainly illustrates components that perform the frequency lock control as the configuration of the control unit 3, for convenience of explanation.

The control unit 3 includes analog-to-digital converters (ADCs) 31, 32, 33, and 34, an arithmetic unit 35, a storage unit 36, and an electric current source 37.

The ADC 31 converts an analog electrical signal input from the PD 71 to a digital signal (voltage signal), and outputs the digital signal to the arithmetic unit 35. The ADC 32 converts an analog electrical signal input from the PD 72 to a digital signal (voltage signal), and outputs the digital signal to the arithmetic unit 35. The ADC 33 converts an analog electrical signal input from the PD 73 to a digital signal (voltage signal), and outputs the digital signal to the arithmetic unit 35. The ADC 34 converts an analog electrical signal input from the temperature sensor 8, and outputs the digital signal to the arithmetic unit 35.

The arithmetic unit 35 that performs digital operation performs various kinds of arithmetic processes for the control performed by the control unit 3, and is configured with, for example, a Central Processing Unit (CPU) or a Field Programmable Gate Array (FPGA). The storage unit 36 includes a part that is configured with, for example, a Read Only Memory (ROM) and stores therein various programs, data, and the like that are used by the arithmetic unit 35 for performing the arithmetic process, and another part that is configured with, for example, a Random Access Memory (RAM) and used as a workspace when the arithmetic unit 35 performs an arithmetic process or used for storing a result of the arithmetic process or the like. Control functions of the control unit 3 are implemented by software by functions of the arithmetic unit 35 and the storage unit 36.

The electric current source 37 supplies electric power to the light source unit 4 for controlling the frequency of the laser light L1, on the basis of an instruction from the arithmetic unit 35. In the present embodiment, the arithmetic unit 35 gives an instruction on a current value as a control amount to the electric current source 37. The electric current source 37 supplies an electric current corresponding to the designated current value to the light source unit 4.

A configuration of the arithmetic unit 35 will be described below. The arithmetic unit 35 includes, as functional units, a target frequency setting unit 351, a discrimination curve selection unit 352, a target value acquisition unit 353, a monitor value calculation unit 354, a difference acquisition unit 355, a PID control unit 356, and a DBR/RING electric power setting unit 357. The functional units as described above are implemented by cooperation of software and hardware resources.

The target frequency setting unit 351 performs a first acquisition step of acquiring and setting a target frequency as a target value for controlling the frequency of the laser light L1 in accordance with an instruction given from a higher-level control apparatus, for example.

The discrimination curve selection unit 352 acquires the target frequency that is set, and selects one of a first frequency discrimination curve, a second frequency discrimination curve, a third frequency discrimination curve, and a fourth frequency discrimination curve based on the target frequency. The first frequency discrimination curve corresponds to the transmission characteristics of the frequency filter 63a. The second frequency discrimination curve corresponds to the transmission characteristics of the frequency filter 64a. The third frequency discrimination curve is represented by a sum of the first frequency discrimination curve and the second frequency discrimination curve. The fourth frequency discrimination curve is represented by a difference between the first frequency discrimination curve and the second frequency discrimination curve.

The first frequency discrimination curve and the second frequency discrimination curve that are standardized such that amplitude values change between −1 and 1 may be represented by sine functions (cosine functions) by Expressions (1) and (2) below based on the assumption that changes occur sinusoidally with respect to a frequency change. Meanwhile, θ=2πf/F. f represents a frequency of light. F represents a cycle or a Free Spectral Range (FRS) of the discrimination curve and is the same as the cycles of the frequency filter 63a and the frequency filter 64a. Further, φ represents a phase difference corresponding to a relative phase shift between the frequency filter 63a and the frequency filter 64a.

sin θ (1)

sin(θ+φ) (2)

The third frequency discrimination curve and the fourth frequency discrimination curve that are standardized such that amplitude values change between −1 and 1 are represented by Expressions (3) and (4) below, for example. Meanwhile, Δ=φ−π/2.

sin(θ+π/4+Δ/2) (3)

sin(θ−π/4+Δ/2) (4)

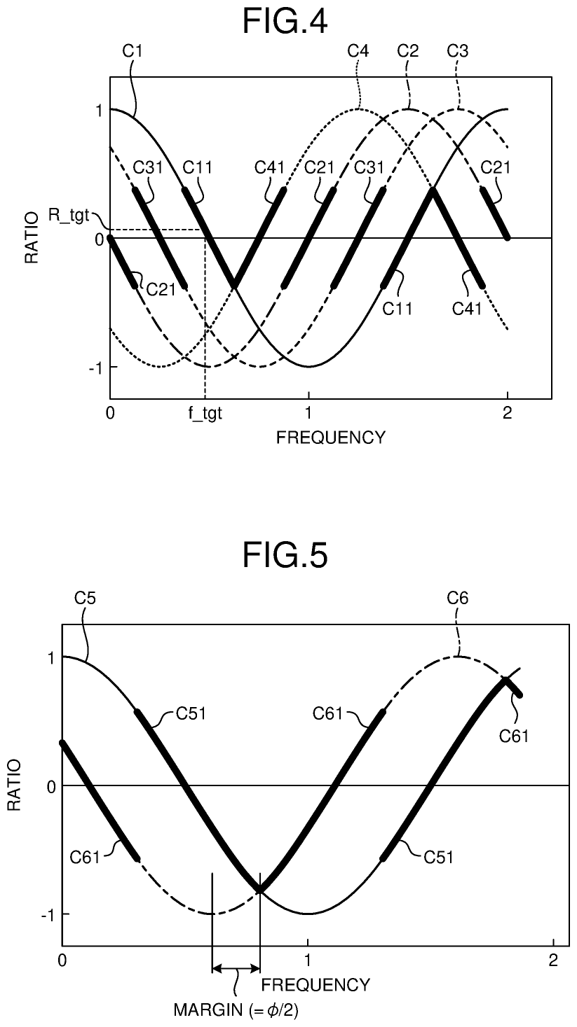

FIG. 4 is a diagram illustrating a first frequency discrimination curve C1, a second frequency discrimination curve C2, a third frequency discrimination curve C3, and a fourth frequency discrimination curve C4 that are standardized such that amplitude values change between −1 and 1. A horizontal axis represents a frequency and is standardized such that a half cycle of the discrimination curve corresponds to 1. A vertical axis represents a ratio that corresponds to a first ratio, a second ratio, a third ratio, and a fourth ratio with respect to each of the first frequency discrimination curve C1, the second frequency discrimination curve C2, the third frequency discrimination curve C3, and the fourth frequency discrimination curve C4. Meanwhile, in FIG. 4, the phase shift φ is set to π/2. Incidentally, even when the phase shift φ between the first frequency discrimination curve and the second frequency discrimination curve is not π/2, if amplitudes of the first frequency discrimination curve and the second frequency discrimination curve are approximately equal to each other, the phase shift between the third frequency discrimination curve and the fourth frequency discrimination curve becomes π/2.

Regions C11, C21, C31, and C42 are regions in which change rates of the ratios with respect to the frequency are large unlike a dead zone and in which control accuracy may be increased in the first to the fourth frequency discrimination curves C1 to C4. The regions C11, C21, C31, and C42 are set such that frequencies do not overlap with one another.

The discrimination curve selection unit 352 selects a frequency discrimination curve corresponding to any of the regions C11, C21, C31, and C42 including a target frequency on the basis of the target frequency. For example, if the target frequency is included in the region C11, the discrimination curve selection unit 352 selects the first frequency discrimination curve C1. In selection of the frequency discrimination curve, it is preferable to select a frequency discrimination curve for which the change rate of the ratio with respect to the frequency is large. In the case illustrated in FIG. 4, it is preferable to select a frequency discrimination curve for which an absolute value of the ratio at the target frequency is small among the plurality of frequency discrimination curves.

The target value acquisition unit 353 performs a third acquisition step of acquiring a target value by applying the target frequency to the frequency discrimination curve that is selected by the discrimination curve selection unit 352. For example, in FIG. 4, if the target frequency is represented by f_tgt, the target frequency is applied to the first frequency discrimination curve C1 and a target value R_tgt is obtained.

The monitor value calculation unit 354 performs a second acquisition step of acquiring a first ratio and a second ratio from digital signals that are input from the ADCs 31, 32, and 33, and performs a step of calculating the third ratio or the fourth ratio. Further, the monitor value calculation unit 354 performs a step of setting one of the first ratio, the second ratio, the third ratio, and the fourth ratio as a monitor value R_mon that corresponds to the frequency of the laser light L1. The monitor value R_mon is one example of a frequency equivalent amount. Meanwhile, while an example in which the target frequency and the frequency of the laser light L1 are present in the same region (for example, the region C11), it is sufficient that the monitor value R_mon and the target value R_tgt are set on the same frequency discrimination curve.

The first ratio is a ratio of the first intensity detected by the PD 71 to the third intensity detected by the PD 73. Further, as a ratio corresponding to the ratio as described above, the first ratio may be a ratio of intensity that is obtained by applying a correction coefficient to the first intensity detected by the PD 71 to intensity that is obtained by applying a correction coefficient to the third intensity detected by the PD 73. Furthermore, as an amount corresponding to the ratio as described above, the first ratio may be a ratio that is calculated by using intensity that is obtained by applying a correction coefficient to one of the first intensity and the third intensity. In the following, the first ratio may be described as PD1/PD3.

The second ratio is a ratio of the second intensity detected by the PD 72 to the third intensity detected by the PD 73. Further, as a ratio corresponding to the ratio as described above, the second ratio may be a ratio of intensity that is obtained by applying a correction coefficient to the second intensity detected by the PD 72 to intensity that is obtained by applying a correction coefficient to the third intensity detected by the PD 73. Furthermore, as an amount corresponding to the ratio as described above, the second ratio may be a ratio that is calculated by using intensity that is obtained by applying a correction coefficient to one of the second intensity and the third intensity. In the following, the second ratio may be described as PD2/PD3.

The correction coefficient for the first intensity, the second intensity, or the third intensity is acquired by experiment or the like in advance, is stored in the storage unit 36 in the form of table data, a relational expression, or the like, and is appropriately read and used by the monitor value calculation unit 354. The correction coefficient may be determined in accordance with, for example, the operating condition of the laser apparatus 1, the temperature detected by the temperature sensor 8, or the like. Further, the correction coefficient may be determined so as to be appropriately applied to a standardized frequency discrimination curve. Application of the correction coefficient to the first intensity, the second intensity, or the third intensity is application by calculation of one of addition, subtraction, multiplication, or division, for example.

The third ratio is a sum of the first ratio and the second ratio. The fourth ratio is a difference between the first ratio and the second ratio. Therefore, the third ratio or the fourth ratio may include the correction coefficient for the first intensity, the second intensity, or the third intensity.

The difference acquisition unit 355 calculates and acquires a difference between the target value R_tgt that is calculated by the target value acquisition unit 353 and the monitor value R_mon that is calculated by the monitor value calculation unit 354.

The PID control unit 356 calculates an designated value of the current value based on the difference between the target value R_tgt and the monitor value R_mon, outputs the designated value to the electric current source 37, and performs feedback control, such as proportional-integral-derivative (PID) control or PI control. In other words, the PID control unit 356 performs an adjustment step of adjusting the current value (control amount) such that an absolute value of the difference between the target value R_tgt and the monitor value R_mon is reduced.

The DBR/RING electric power setting unit 357 sets electric power to be supplied to each of the DBR heater 421 and the RING heater 422, on the basis of the target frequency that is set by the target frequency setting unit 351. The DBR/RING electric power setting unit 357 is able to set a current value based on the set electric power, output an instruction on the current value to the electric current source 37, and perform feed-forward control on the DBR heater 421 and the RING heater 422.

In the laser apparatus 1 configured as described above, it is possible to prevent a control target frequency from unintentionally overlapping with the dead zone, so that it is possible to prevent reduction in control accuracy of the frequency of the laser light.

In the following, the reason that the control target frequency and the dead zone are less likely to overlap with each other when a lateral shift occurs will be described while introducing a parameter of a “margin”. The margin is a parameter that serves as an evaluation index for resistance of a frequency monitoring and control system against a lateral shift.

FIG. 5 is a diagram for explaining the margin. In FIG. 5, a fifth frequency discrimination curve C5 and a sixth frequency discrimination curve C6 that are sine functions that are standardized such that amplitude values change between −1 and 1. Regions C51 and C61 are regions in which change rates of ratios with respect to frequency are large unlike the dead zone and control accuracy may be improved in the fifth and the sixth frequency discrimination curves C5 and C6. The regions C51 and C61 are set such that frequencies do not overlap with each other.

In FIG. 5, the margin is defined as a frequency difference between a point that is closest to an extreme value among switching points of the two frequency discrimination curves and a center of the dead zone, in other words, an extreme value (a local minimum in FIG. 5) of the frequency discrimination curve. With an increase in the margin, it is possible to monitor the frequency of the laser light L1 in a region that is more distant from the dead zone in terms of the frequency, so that resistance against a lateral shift is increased. Meanwhile, when the frequency control is performed while the two frequency discrimination curves are switched as in FIG. 5, the margin is set to φ/2.

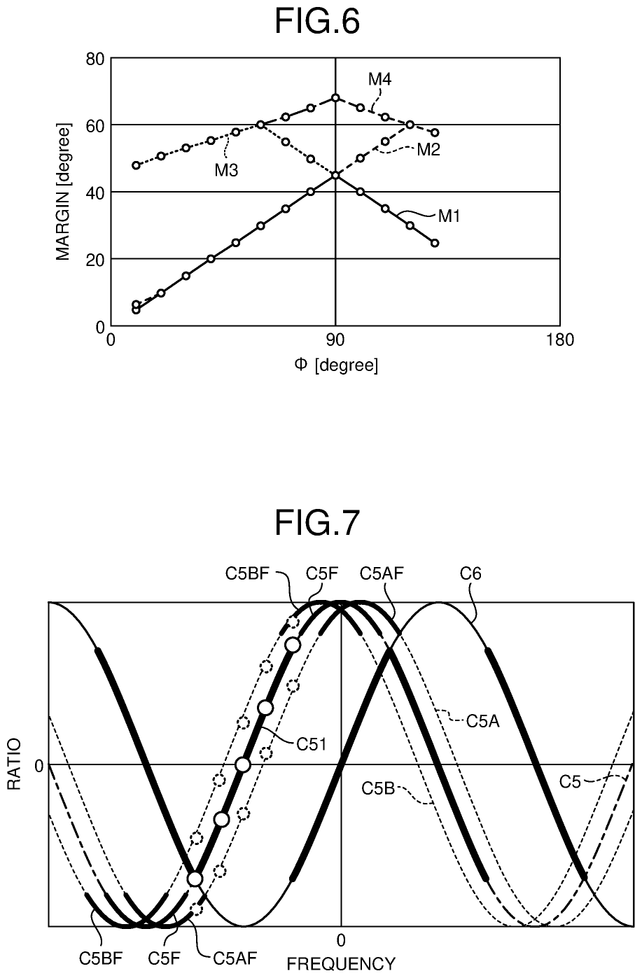

FIG. 6 is a diagram illustrating a relationship between φ and the margin. A line M1 indicates a relationship between φ and the margin in a case where the two frequency discrimination curves, that is, the first and the second frequency discrimination curves as represented by Expressions (1) and (2) are used. A line M2 indicates a relationship between φ and the margin in a case where the three frequency discrimination curves, that is, the first to the third frequency discrimination curve as represented by Expressions (1) to (3) are used. The line M2 overlaps with the line M1 when φ is equal to or smaller than 90 degrees. A line M3 indicates a relationship between φ and the margin in a case where the three frequency discrimination curves, that is, the first, the second, and the fourth frequency discrimination curve as represented by Expressions (1), (2), and (4) are used. The line M3 overlaps with the line M1 when φ is equal to or smaller than 90 degrees. A line M4 indicates a relationship between φ and the margin in a case where the four frequency discrimination curves, that is, the first to the fourth frequency discrimination curves as represented by Expressions (1) to (4) are used. The line M4 overlaps with the line M3 when φ is equal to or smaller than 60 degrees and overlaps with the line M2 when φ is equal to or larger than 120.

As illustrated in FIG. 6, if the four frequency discrimination curves, that is, the first to the fourth frequency discrimination curves, are used, the margin is increased at every φ, so that it is confirmed that the resistance of the frequency monitoring and control system against a lateral shift is increased.

FIG. 7 is a diagram illustrating temperature-dependent changes of frequency discrimination curves according to a comparative example. The comparative example is a mode in which, in the laser apparatus 1, the frequency control is performed by using only the first and the second frequency discrimination curves.

FIG. 7 illustrates the fifth frequency discrimination curve C5 and the sixth frequency discrimination curve C6 similarly to FIG. 5. However, a phase shift between the fifth frequency discrimination curve C5 and the sixth frequency discrimination curve C6 is set to π/2. Here, in the region C51, points on the fifth frequency discrimination curve C5 corresponding to four exemplary target frequencies are represented by bold white circles. In contrast, a frequency discrimination curve C5A indicates a state in which the fifth frequency discrimination curve C5 is laterally shifted toward a positive frequency side due to a temperature change, and a frequency discrimination curve C5B indicates a state in which the fifth frequency discrimination curve C5 is laterally shifted toward a negative frequency side due to a temperature change. Regions C5F, C5AF, and C5BF represent respective dead zones in the fifth frequency discrimination curve C5, the frequency discrimination curve C5A, and the frequency discrimination curve C5B.

If the state indicated by the frequency discrimination curve C5A occurs due to the lateral shift, as indicated by dashed white circles, a point that is located on the most negative side among the four target frequencies overlap with the dead zone C5AF due to the lateral shift. Further, if the state indicated by the frequency discrimination curve C5B occurs due to the lateral shift, as indicated by dashed white circles, a point that is located on the most positive side among the four target frequencies overlap with the dead zone C5BF due to the lateral shift. This indicates that, in the comparative example, resistance against a lateral shift is low.

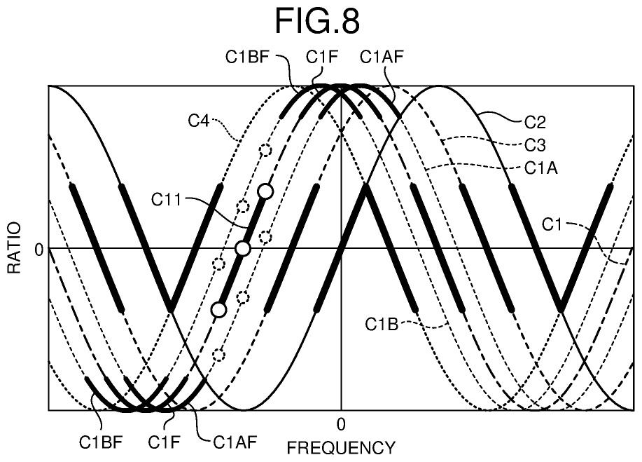

In contrast, FIG. 8 is a diagram illustrating temperature-dependent changes of the frequency discrimination curves according to the embodiment. FIG. 8 illustrates the first to the fourth frequency discrimination curves C1 to C4 similarly to FIG. 4. Here, in the region C11, points on the first frequency discrimination curve C1 corresponding to three exemplary target frequencies are represented by bold white circles. In contrast, a frequency discrimination curve CIA indicates a state in which the first frequency discrimination curve C1 is laterally shifted to a positive frequency side due to a temperature change, and a frequency discrimination curve C1B indicates a state in which the first frequency discrimination curve C1 is laterally shifted to a negative frequency side due to a temperature change. Regions C1F, C1AF, and C1BF represent respective dead zones in the first frequency discrimination curve C1, the frequency discrimination curve CIA, and the frequency discrimination curve C1B.

In the embodiment, even if the state indicated by the frequency discrimination curve CIA occurs due to the lateral shift, as indicated by dashed white circles, all of the points at the three target frequencies do not overlap with the dead zone C1AF. Further, even if the state indicated by the frequency discrimination curve C1B occurs due to the lateral shift, as indicated by dashed white circles, all of the three target frequencies do not overlap with the dead zone C1BF. This indicates that the resistance against a lateral shift is increased in the embodiment.

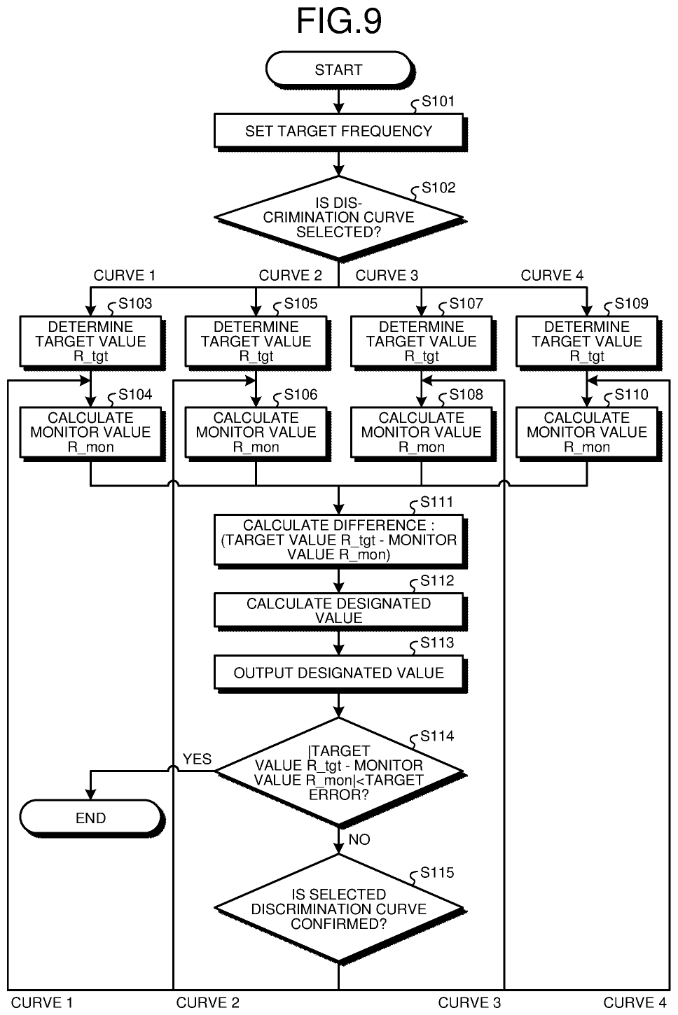

A control method performed by the laser apparatus 1 will be described below with reference to a flowchart in FIG. 9.

First, at Step S101, the target frequency setting unit 351 sets a target frequency as a target value of the frequency of the laser light L1. Subsequently, although not illustrated in the drawing, the DBR/RING electric power setting unit 357 sets electric power to be supplied to each of the DBR heater 421 and the RING heater 422 on the basis of the target frequency that is set by the target frequency setting unit 351, and outputs a designated value of a current value corresponding to the electric power to the electric current source 37.

Subsequently, at Step S102, the discrimination curve selection unit 352 selects one of the first frequency discrimination curve, the second frequency discrimination curve, the third frequency discrimination curve, and the fourth frequency discrimination curve based on the target frequency. For example, it may be possible to select, from among the first frequency discrimination curve, the second frequency discrimination curve, the third frequency discrimination curve, and the fourth frequency discrimination curve, a frequency discrimination curve for which the change rate at the target frequency set at Step S101 is maximized, or a frequency discrimination curve for which an absolute value is minimized in a target frequency after standardizing all of the frequency discrimination curves such that the amplitude values vary between −1 and 1.

If the first frequency discrimination curve is selected (Step S102, a curve 1), at Step S103, the target value acquisition unit 353 acquires and determines the target value R_tgt that corresponds to the target frequency based on the first frequency discrimination curve. Subsequently, at Step S104, the monitor value calculation unit 354 calculates and sets the monitor value R_mon that corresponds to the frequency of the laser light L1 based on the first frequency discrimination curve. Thereafter, the flow goes to Step S111.

If the second frequency discrimination curve is selected (Step S102, a curve 2), at Step S105, the target value acquisition unit 353 acquires and determines the target value R_tgt that corresponds to the target frequency based on the second frequency discrimination curve. Subsequently, at Step S106, the monitor value calculation unit 354 calculates and sets the monitor value R_mon that corresponds to the frequency of the laser light L1 based on the second frequency discrimination curve. Thereafter, the flow goes to Step S111.

If the third frequency discrimination curve is selected (Step S102, a curve 3), at Step S107, the target value acquisition unit 353 acquires and determines the target value R_tgt that corresponds to the target frequency based on the third frequency discrimination curve. Subsequently, at Step S108, the monitor value calculation unit 354 calculates and sets the monitor value R_mon that corresponds to the frequency of the laser light L1 based on the third frequency discrimination curve. Thereafter, the flow goes to Step S111.

If the fourth frequency discrimination curve is selected (Step S102, a curve 4), at Step S109, the target value acquisition unit 353 acquires and determines the target value R_tgt that corresponds to the target frequency based on the fourth frequency discrimination curve. Subsequently, at Step S110, the monitor value calculation unit 354 calculates and sets the monitor value R_mon that corresponds to the frequency of the laser light L1 based on the fourth frequency discrimination curve. Thereafter, the flow goes to Step S111.

Subsequently, at Step S111, the difference acquisition unit 355 calculates and acquires the difference between the target value R_tgt and the monitor value R_mon (the target value R_tgt−the monitor value R_mon).

Then, at Step S112, the PID control unit 356 calculates a designated value of a current value such that an absolute value of the difference between the target value R_tgt and the monitor value R_mon is reduced.

Subsequently, at Step S113, the PID control unit 356 outputs the calculated designated value to the electric current source 37.

Then, at Step S114, the PID control unit 356 determines whether |the target value R_tgt−the monitor value R_mon| that is the absolute value of the difference falls within a target margin of error. If it is determined that the absolute value does not fall within the target margin of error (Step S114, No), the process control goes to S115.

At Step S115, the control unit 3 confirms the discrimination curve that is selected by the discrimination curve selection unit 352. If it is confirmed that the first frequency discrimination curve is selected (Step S115, the curve 1), the flow returns to Step S104. If it is confirmed that the second frequency discrimination curve is selected (Step S115, the curve 2), the flow returns to Step S106. If it is confirmed that the third frequency discrimination curve is selected (Step S115, the curve 3), the flow returns to Step S108. If it is confirmed that the fourth frequency discrimination curve is selected (Step S115, the curve 4), the flow returns to Step S110.

In contrast, at Step S114, if the PID control unit 356 determines that |the target value R_tgt−the monitor value R_mon| falls within the target margin of error (Step S114, Yes), the control is terminated.

As described above, in the laser apparatus 1, it is possible to prevent the control target frequency from unintentionally overlapping with the dead zone, so that it is possible to prevent reduction in control accuracy of the frequency of the laser light.

Further, in the laser apparatus 1, the four frequency discrimination curves are generated by the two frequency filters 63a and 64a, so that it is possible to largely reduce complexity of a configuration and control of the laser apparatus as compared to a case in which the number of the frequency filters is increased. Furthermore, the detection unit for detecting intensity of laser light is shared to some extent by the frequency discrimination curves, so that it is not necessary to switch between detection units every time the frequency discrimination curve is switched. As a result, it is possible to prevent a situation in which control becomes unstable when the frequency discrimination curve is switched.

Moreover, in the laser apparatus 1, it is possible to calculate the first ratio or the second ratio by applying the correction coefficient to the first intensity, the second intensity, or the third intensity. Accordingly, it is possible to calculate the first ratio or the second ratio, or further calculate the third ratio or the fourth ratio in accordance with appropriateness of application to the operating condition of the laser apparatus 1, the temperature detected by the temperature sensor 8, or the frequency discrimination curve. Specifically, it is possible to set the correction coefficient so as to correct a lateral shift of a frequency filter that is dependent on temperature or set the correction coefficient so as to correct a vertical shift of a frequency filter that is dependent on temperature, in accordance with the temperature detected by the temperature sensor 8. Here, the vertical shift of the frequency filter means that the transmission characteristic of the frequency filter is shifted in a transmittance axial direction. The vertical shift may become a cause of uncontrol of the target frequency or a cause of setting of a target value that is not achievable. Furthermore, for example, if the transmission characteristics of the frequency filters 63a and 64a are not sine functions of a frequency, it may be possible to perform correction such that the first intensity, the second intensity, or the third intensity is applicable to the frequency discrimination curve that is a sine function of a frequency by using the correction coefficient. Meanwhile, if the temperature sensor 8 is mounted on the first area Ar1, if a second temperature sensor is mounted separately from the temperature sensor 8 (first temperature sensor), and if the electric power to be supplied to the temperature controller 9 is controlled based on information on the temperature detected by the temperature sensor 8, it may be possible to set the correction coefficient so as to correct at least one of a lateral shift and a vertical shift of the frequency filter based on information on temperature detected by the second temperature sensor. In this case, the second temperature sensor may be mounted on the second area Ar2 or may be mounted closer to the planar lightwave circuit 6 than the light source unit 4. As another example, it may be possible to mount the sensor in a place different from the laser unit 2 (for example, outside a casing if the laser unit 2 is stored in the casing).

Furthermore, if the transmission characteristics of the frequency filters 63a and 64a are periodic functions different from sine functions of a frequency, it may be possible to derive and use a function for conversion to sine functions by using the fast Fourier transform (FFT) or the inverse fast Fourier transform (IFFT). For example, it may be possible to accumulate digital signals that are converted by the ADCs 31 and 32 for one period or more, apply the FFT to the digital signals to eliminate components other than FSR of the frequency filters 63a and 64a, and perform conversion to sine functions by applying the IFFT. Conversion to the sine functions is performed with use of the function that is derived as described above. Meanwhile, frequency transmission characteristics of an MZI filter may be handled as a change that occurs sinusoidally with respect to a frequency change, so that when the MZI filter is used as each of the frequency filters 63a and 64a, it is not necessary to perform conversion to sine functions using the FFT and the IFFT. When ring resonator filters are used as the frequency filters 63a and 64a, and if Q values of the frequency transmission characteristics of the filters are small, the changes may be handled as changes that occur sinusoidally with respect to the frequency change.

Moreover, in the laser apparatus 1, the single temperature controller 9 controls temperature of both of the light source unit 4 and the planar lightwave circuit 6, so that it is possible to realize low power consumption and low cost as compared to a case in which a temperature controller is arranged for each of the light source unit 4 and the planar lightwave circuit 6. However, if the control unit 3 controls electric power to be supplied to the temperature controller 9 mainly for maintaining constant temperature of the light source unit 4 or controls an oscillation frequency of laser light that is output by the light source unit 4 by controlling the electric power to be supplied to the light source unit 4, a lateral shift that is dependent on temperature may easily occur in the frequency filters 63a and 64a of the planar lightwave circuit 6. To cope with this, the laser apparatus 1 has a structure with high resistance against a lateral shift, and therefore is preferable to prevent reduction in the control accuracy.

Furthermore, in the laser apparatus 1, the third ratio and the fourth ratio include information on both of the first ratio that reflects the characteristic of the frequency filter 63a and the second ratio that reflects the characteristics of the frequency filter 64a. This means that if a voltage value of one of the first ratio and the second ratio is changed by even 1 bit with respect to the frequency in the digital signal converted by the ADCS 31, 32, and 33, the change is detectable. In other words, even if the target value or the monitor value falls in the dead zone due to a lateral shift or the like or even if the phase shift φ is close to 0 or n, it is possible to detect a change of the monitor value, which means that the frequency control may be performed.

Moreover, in the laser apparatus 1, the first ratio or the second ratio is calculated by applying the correction coefficient to the first intensity, the second intensity, or the third intensity, but it may be possible to apply the correction coefficient when the target value acquisition unit 353 acquires a target value from a target frequency. The correction coefficient is acquired in advance by an experiment or the like and stored in the storage unit 36, and may be set in accordance with the operating condition of the laser apparatus 1 or the temperature detected by the temperature sensor 8 or the second temperature sensor. In addition, when the target value is to be acquired from the target frequency, it may be possible to acquire the target value from the target frequency by using the same method as the method of performing conversion from other than a sine function to a sine function by using the FFT and the IFFT.

Furthermore, in the laser apparatus 1, calculation, such as addition and subtraction, for calculating the third ratio and the fourth ratio is performed by digital calculation by the arithmetic unit 35, but it may be possible to perform calculation, such as addition and subtraction, by using an analog circuit. With use of the digital calculation, it is possible to reduce the number of elements to be used and a circuit size, so that it is possible to reduce cost. In addition, with use of the analog circuit, it is possible to prevent occurrence of information missing due to quantization at the time of digitization.

In a first modification of the laser apparatus 1, a temperature sensor that detects environmental temperature of the frequency filters 63a and 64a may further be provided. Further, the arithmetic unit 35 may correct the control temperature of the temperature controller 9 and the first ratio or the second ratio such that changes of the transmission characteristics of the frequency filters 63a and 64a due to the environmental temperature are cancelled out, on the basis of the environmental temperature that is detected by the environmental temperature sensor.

The environmental temperature sensor is configured with, for example, a thermistor or the like. Meanwhile, it is sufficient that the environmental temperature sensor is arranged at a position at which the environmental temperature of the frequency filters 63a and 64a is detectable, and the position is not specifically limited; for example, if the laser unit 2 is stored in a casing, the environmental temperature sensor may be arranged outside the casing, and may be arranged in, for example, the control unit 3. The environmental temperature sensor outputs an electrical signal that includes information on the detected temperature to an ADC of the control unit 3. The ADC converts an analog electrical signal that is input from the environmental temperature sensor to a digital signal and outputs the digital signal to the arithmetic unit 35.

If the environmental temperature changes, the temperature of each of the frequency filters 63a and 64a changes even when the temperature controller 9 is controlled so as to maintain constant temperature of the light source unit 4, so that a lateral shift or a vertical shift may occur in the first to the fourth frequency discrimination curves.

The vertical shift or the lateral shift may similarly occur due to a different cause. Examples of the different cause include a change of a heat generation amount of the semiconductor optical amplifier 5 (a change of the heat generation amount of the SOA) with a change of the intensity of the laser light L2, and a temporal change of each of the frequency filters 63a and 64a due to a long-term use of the laser apparatus 1. The frequency characteristics of the frequency filters 63a and 64a may temporally change when the laser apparatus 1 is used for a long time and approaches the end of life. Hereinafter, a temporal and unintentional change of the characteristics of each of the frequency filters 63a and 64a due to the long-term use as described above will be referred to as deterioration. Hereinafter, a lateral shift or a vertical shift due to a change of the environmental temperature and correction of the lateral shift and the vertical shift will be mainly described, but a lateral shift or a vertical shift due to a different cause may be corrected in the same manner.

If a lateral shift or a vertical shift due to the environmental temperature occurs, in the control method implemented by the laser apparatus 1, the arithmetic unit sets a temperature correction coefficient for correcting target temperature of the ambient temperature of the light source unit 4 (control target temperature of the temperature controller 9) on the basis of the environmental temperature of the frequency filters 63a and 64a detected by the environmental temperature sensor. The frequency filters 63a and 64a are arranged such that temperature thereof changes in accordance with control of the temperature controller 9. As a result, by correcting the target temperature, a thermal influence of the temperature controller 9 on the frequency filters 63a and 64a is changed, so that the temperature of the frequency filters 63a and 64a is changed. With respect to the temperature change as described above, by setting the temperature correction coefficient such that changes of the transmission characteristics of the frequency filters 63a and 64a due to the environmental temperature are cancelled out, it is possible to reduce a lateral shift or a vertical shift of the first to the fourth discrimination curves due to the environmental temperature. Here, the cancellation out is not limited to complete cancellation out of the lateral shift or the vertical shift of the first to the fourth discrimination curves due to the environmental temperature, but includes what is called diminishing, that is, cancellation out for reducing the lateral shift or the vertical shift as compared to a case in which target temperature is not corrected. Further, application of the correction coefficient is, for example, application by calculation of any of addition, subtraction, multiplication, and division.

One example of a relationship between the environmental temperature and the temperature correction coefficient is illustrated in Table 1. The relationship is acquired when calibration is performed at the time of manufacturing, shipping, maintenance, or the like of the laser apparatus 1, for example. In Table 1, the temperature correction coefficient is represented as LD offset temperature. In the example illustrated in Table 1, it is assumed that the environmental temperature varies between −5° C. and 80° C. For example, the target temperature of the light source unit 4 is set to a predetermined value that is higher than 35° C. and smaller than 80° C. If the environmental temperature is 35° C., the LD offset temperature is 0° C. If the environmental temperature is −5° C., the LD offset temperature is ΔT1 (° C.). If the environmental temperature is 80° C., the LD offset temperature is ΔT2 (° C.). ΔT1 and ΔT2 are used for correction by being added to the target temperature. ΔT1 is, for example, a positive value and ΔT2 is, for example, a negative value. The relationship as described above is stored, as first relational information on the environmental temperature and the temperature correction coefficient, in the storage unit 36. The first relational information includes table data or a relational expression in which the environmental temperature and the temperature correction coefficient are associated with each other. Meanwhile, the LD offset temperature at the environmental temperature of a certain value other than −5° C., 35° C., or 80° C. may be stored as table data or a relational expression in the storage unit 36, or may be calculated by interpolation from the LD offset temperature at the environmental temperature of −5° C., 35° C., or 80° C. In the following, the environmental temperature at the LD offset temperature of 0° C. may be described as reference temperature. In Table 1, the reference temperature is set to 35° C.

TABLE 1

| Environmental | LD Offset |
|---|---|
| Temperature [° C.] | Temperature [° C.] |
| −5 | ΔT1 |
| . | . |
| . | . |
| . | . |
| 35 | 0 |
| . | . |
| . | . |
| . | . |
| 80 | ΔT2 |

The same applies to a case where a lateral shift or a vertical shift occurs due to a change of the heat generation amount of the SOA or due to deterioration of the frequency filters 63a and 64a. As for a shift caused by a change of the heat generation amount of the SOA, the temperature correction coefficient is determined by determining, in the same manner as above, a relationship between the heat generation amount of the SOA or a current value of the SOA (a value of the electric current that is supplied to the semiconductor optical amplifier 5) and the temperature correction coefficient. As for a shift caused by the deterioration of the frequency filters 63a and 64a, the temperature correction coefficient is determined by determining, in the same manner as above, a relationship between a certain amount that reflects a degree of deterioration and the temperature correction coefficient. The certain amount that reflects the degree of deterioration is, for example, the number of times of variation of the environmental temperature, and the total number of times of variation of temperature in a range exceeding a predetermined range. Alternatively, the certain amount may be a certain time, that is, a total time in which the laser apparatus 1 is in certain operating conditions in a predetermined range. Still alternatively, it may be possible to adopt, as a deterioration function, a predetermined function in which a weight is added to each of amounts, such as the number of times of variation of the environmental temperature or a total time in which the laser apparatus 1 is in the predetermined operating condition, and use an output value of the deterioration function as an amount that reflects the degree of deterioration.

It may be possible to adopt, as the final correction coefficient for the target temperature of the temperature controller 9, a sum of the temperature correction coefficients that are determined for respective causes of a lateral shift or a vertical shift.

Furthermore, the discrimination curves as illustrated in FIG. 4 may be shifted in a comparison axis direction, other than the frequency axis direction, due to a change of the environmental temperature or the like. Occurrence of the shift called a vertical shift as described above may lead to reduction in accuracy of the frequency lock.

To cope with this, the arithmetic unit 35 may set a ratio correction coefficient in accordance with the environmental temperature, and correct the first ratio or the second ratio in accordance with the ratio correction coefficient. In this case, the storage unit 36 stores therein second relational information that indicates a relationship between the environmental temperature and the ratio correction coefficient. The second relational information includes table data or a relational expression in which the environmental temperature and the ratio correction coefficient are associated with each other. The arithmetic unit 35 sets the ratio correction coefficient by referring to the storage unit 36. The ratio correction coefficient is set so as to cancel out a vertical shift corresponding to the environmental temperature. With this configuration, it is possible to prevent reduction in the accuracy of the frequency lock. For example, the ratio correction coefficient may be set with reference to a local maximum point or a local minimum point of the transmission characteristics of the frequency filter 63a or 64a. As a specific example, the ratio correction coefficient may be set such that an extreme point in the first or the second frequency discrimination curve that has vertically shifted and an extreme point in the first or the second frequency discrimination curve at reference temperature match with each other. This means that an amplitude of the frequency discrimination curve that has vertically shifted is adjusted to the original frequency discrimination curve by application of the ratio correction coefficient. Meanwhile, the extreme point is a local maximum point or a local minimum point. Further, application of the ratio correction coefficient is application by calculation of any of addition, subtraction, multiplication, and division for example; however, if the vertical shift occurs in both of the amplitude of the curve and offset of the curve, the ratio correction coefficient is set as a combination of a correction coefficient for the amplitude and a correction coefficient for the offset. As a specific example, the ratio correction coefficient is set such that a pair of a local maximum and a local minimum of the first or the second frequency discrimination curve that has vertically shifted and a pair of a local maximum and a local minimum of the first or the second frequency discrimination curve at corresponding reference temperature match with each other.

Further, the arithmetic unit 35 may set the ratio correction coefficient in accordance with the heat generation amount of the SOA, and correct the first ratio or the second ratio by the ratio correction coefficient. In this case, the storage unit 36 stores therein third relational information that indicates a relationship between the heat generation amount of the SOA and the ratio correction coefficient. The third relational information includes table data or a relational expression in which the heat generation amount of the SOA and the ratio correction coefficient are associated with each other. The arithmetic unit 35 sets the ratio correction coefficient by referring to the storage unit 36. The ratio correction coefficient is set so as to cancel out a vertical shift corresponding to the heat generation amount of the SOA. With this configuration, it is possible to prevent reduction in the accuracy of the frequency lock. For example, the ratio correction coefficient may be set with reference to the local maximum point or the local minimum point of the transmission characteristics of the frequency filter 63a or 64a. As a specific example, it may be possible to set the ratio correction coefficient such that that the extreme point in the first or the second frequency discrimination curve that has vertically shifted and the extreme point in the first or the second frequency discrimination curve at a reference heat generation amount of the SOA match with each other. This means that an amplitude of the frequency discrimination curve that has vertically shifted is adjusted to the original frequency discrimination curve by application of the ratio correction coefficient. Meanwhile, the extreme point is a local maximum point or a local minimum point. Further, the reference heat generation amount of the SOA is a heat generation amount of the SOA when the laser light L2 has reference intensity, and is acquired when calibration is performed at the time of manufacturing, shipping, maintenance, or the like of the laser apparatus 1, for example. Furthermore, application of the ratio correction coefficient is application by calculation of any of addition, subtraction, multiplication, and division for example; however, if the vertical shift occurs both in the amplitude of the curve and offset of the curve, the ratio correction coefficient is set as a combination of a correction coefficient for the amplitude and a correction coefficient for the offset. As a specific example, the ratio correction coefficient is set such that a pair of a local maximum and a local minimum of the first or the second frequency discrimination curve that has vertically shifted and a pair of a local maximum and a local minimum of the first or the second frequency discrimination curve at a corresponding reference heat generation amount of the SOA match with each other.

Moreover, the arithmetic unit 35 may set the ratio correction coefficient in accordance with the amount that reflects the degree of deterioration, and correct the first ratio or the second ratio by the ratio correction coefficient. In this case, the storage unit 36 stores therein fourth relational information that indicates a relationship between the amount that reflects the degree of deterioration and the ratio correction coefficient. The fourth relational information includes table data or a relational expression in which the amount that reflects the degree of deterioration and the ratio correction coefficient are associated with each other. The arithmetic unit 35 sets the ratio correction coefficient by referring to the storage unit 36. The ratio correction coefficient is set so as to cancel out the vertical shift caused by the deterioration of the frequency filters 63a and 64a. With this configuration, it is possible to prevent reduction in the accuracy of the frequency lock. For example, the ratio correction coefficient may be set with reference to the local maximum point or the local minimum point of the transmission characteristics of the frequency filter 63a or 64a. As a specific example, the ratio correction coefficient may be set such that an extreme point in the first or the second frequency discrimination curve that has vertically shifted due to the deterioration and the extreme point of the first or the second frequency discrimination curve at the time of manufacturing the laser apparatus 1 match with each other. This means that an amplitude of the frequency discrimination curve that has vertically shifted due to the deterioration is adjusted to the original frequency discrimination curve by application of the ratio correction coefficient. Meanwhile, the extreme point is a local maximum point or a local minimum point. Further, application of the ratio correction coefficient is application by calculation of any of addition, subtraction, multiplication, and division for example; however, if the vertical shift occurs both in the amplitude of the curve and offset of the curve, the ratio correction coefficient is set as a combination of a correction coefficient for the amplitude and a correction coefficient for the offset. As a specific example, the ratio correction coefficient is set such that a pair of a local maximum and a local minimum of the first or the second frequency discrimination curve that has vertically shifted and a pair of a local maximum and a local minimum of the first or the second frequency discrimination curve at the time of manufacturing of the laser apparatus 1 match with each other.

It may be possible to simultaneously correct vertical shifts caused by a plurality of factors, by sequentially applying the ratio correction coefficients that are determined for the respective factors of the vertical shifts.

When both of the temperature correction coefficient for cancelling out the lateral shift and the ratio correction coefficient for cancelling out the vertical shift are set, it is possible to more effectively prevent reduction in the accuracy of the frequency lock by first setting the ratio correction coefficient and thereafter setting the temperature correction coefficient.

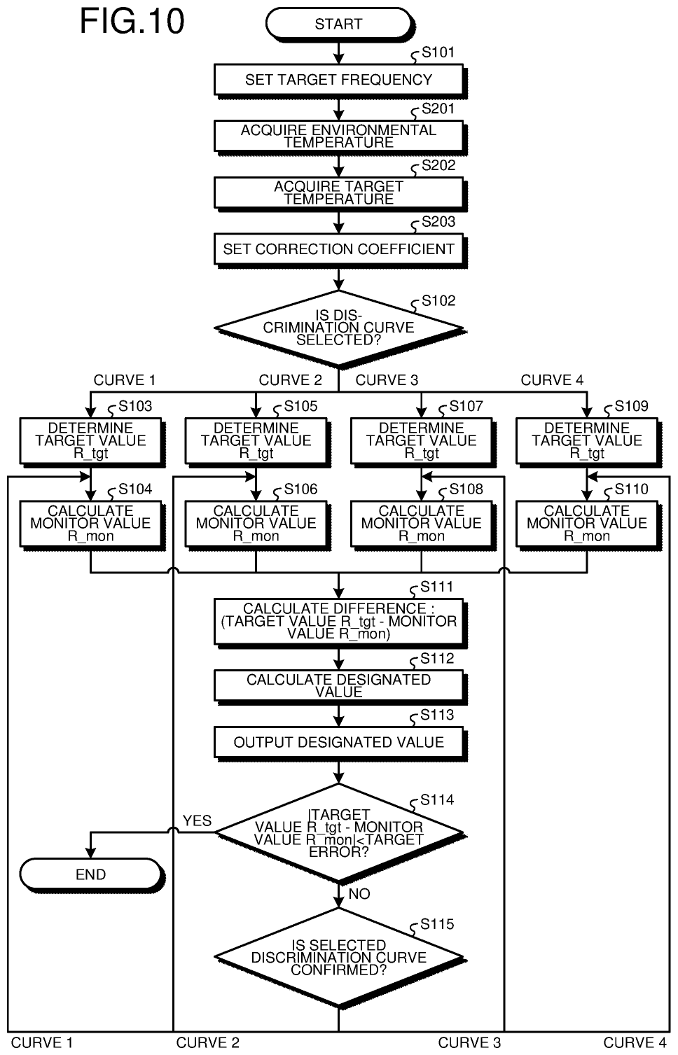

FIG. 10 is a flowchart illustrating a control method for performing correction in accordance with the environmental temperature. The flowchart in FIG. 10 includes Steps S201 to S203 in addition to Steps in the flowchart in FIG. 9, and therefore, Steps S201 to S203 will be described below, and explanation of Steps S101 to S115 will be omitted.

In the control method illustrated in FIG. 10, at Step S201 following Step S101, the control unit 3 acquires the environmental temperature. Subsequently, at Step S202, the control unit 3 acquires the target temperature. Then, at Step S203, the control unit 3 sets the correction coefficient, in other words, the temperature correction coefficient and the ratio correction coefficient. Subsequently, the process control goes to S102.

The modification of the laser apparatus 1 and the control method illustrated in the flowchart in FIG. 10 are preferable because it is possible to always apply the frequency control at the reference temperature even if the environmental temperature especially varies, so that it is possible to further improve resistance against a lateral shift and a vertical shift that is caused especially by a change of the environmental temperature.

Furthermore, in the modification and the control method as described above, it is possible to achieve an effect to optimally correct the third ratio and the fourth ratio that are obtained by calculation of the first ratio and the second ratio, even if an individual correction coefficient is not prepared. Therefore, only by simple correction of the first ratio and the second ratio, it is possible to realize frequency control that is equivalent to the reference temperature even if the environmental temperature varies.

Moreover, it may be possible to set a different correction coefficient for each of the first ratio and the second ratio. With this configuration, it is possible to perform optimal correction even if an influence of stray light or the like differs between the first ratio and the second ratio.

Furthermore, it may be possible to apply a monitor correction coefficient to a monitor value instead of applying the ratio correction coefficient to the first ratio or the second ratio. The monitor coefficient is set so as to cancel out a vertical shift corresponding to the environmental temperature.

Moreover, in the flowchart in FIG. 10, the positions of Steps at which Steps S201 to S203 are performed are not limited to the example as described above. By performing Steps S201 to S203, a shift of the frequency discrimination curve is corrected and the frequency discrimination curve matches with the frequency discrimination curve at the reference temperature. Therefore, it is possible to achieve the same effects by performing Steps related to the correction as described above before a step of calculating and setting the monitor value R_mon corresponding to the frequency of the laser light L1, which is Step S104, S106, S108, or S110.

It is explained that, in the flowchart in FIG. 9, it is possible to select the frequency discrimination curve for which the change rate is maximized at the target frequency among the first to the fourth ratios, and it is possible to standardize the amplitude of the frequency discrimination curve and select the frequency discrimination curve for which the absolute value is minimized at the target frequency. In contrast, in a second modification of the laser apparatus 1, the control unit 3 may give priorities to the first to the fourth ratios and select a ratio that is set as a monitor value corresponding to the frequency of the laser light, on the basis of the change rate of the ratio with respect to a frequency change at a target value.

Furthermore, in a third modification of the laser apparatus 1, the control unit 3 may give priorities to the first to the fourth ratios and select a ratio that is set as a monitor value corresponding to the frequency of the laser light, on the basis of a signal-to-noise (S/N) ratio with respect to a frequency change at the target value.

Specifically, the laser light L5 that has transmitted through the frequency filter 63a or an electrical signal that is output from the PD 71 to which the laser light L5 has been input may include noise due to an influence of stray light or electrical noise, and the S/N may be degraded in some cases. Similarly, the laser light L6 that has transmitted through the frequency filter 64a or an electrical signal that is output from the PD 72 to which the laser light L6 has been input may include noise due to an influence of stray light or electrical noise, and the S/N may be degraded in some cases. Further, relative intensity of stray light with respect to the laser light L5 or the laser light L6 may temporally change due to deterioration, and the S/N may be degraded in some cases. If the S/N is degraded, the frequency of the laser light may vary and frequency stability may be reduced. To cope with this, for example, if selection priority of the frequency discrimination curve, for which the change rate of the ratio is large but the S/N is degraded, is reduced, it is possible to prevent or reduce degradation of the S/N, so that it is possible to prevent or reduce reduction in the frequency stability.

Furthermore, in a fourth modification of the laser apparatus 1, the control unit 3 may give priorities to the first to the fourth ratios and select a ratio that is set as a monitor value corresponding to the frequency of the laser light, on the basis of the change rate of the ratio with respect to a frequency change at the target value and on the basis of the S/N. With this configuration, it is possible to more appropriately select the frequency discrimination curve.

The priorities may be given such that, for example, the highest priority is given to a frequency discrimination curve for which the change rate is larger than a first threshold for the change rate and the S/N is higher than a second threshold for the S/N, and the second highest priority is given to a frequency discrimination curve for which the change rate is equal to or smaller than the first threshold but the S/N is higher than the second threshold. Furthermore, for example, it may be possible to give priorities in order from the largest value of an evaluation function by applying, as the evaluation function, a predetermined function in which a weight is applied to each of the change rate and the S/N that are parameters. A rule for giving priorities as described above may be set in accordance with specifications needed for the laser apparatus, for example. Meanwhile, the degree of the S/N may be quantitatively evaluated by being converted to a variation range (frequency stability) of the frequency of the laser light.

The three kinds of priority setting (the change rate, the S/N, and the S/N and the change rate) are acquired when calibration is performed at the time of manufacturing, shipping, maintenance, or the like of the laser apparatus 1 of the second to the fourth modifications for example, and stored as table data or the like in the storage unit 36. Further, the priority setting may be re-written at the time of maintenance of the laser apparatus 1 of the modifications. The S/N may be acquired by monitoring the electrical signal that is output from the PD 71 or the electrical signal that is output from the PD 72. Furthermore, the S/N may be acquired by measuring frequency stability of the laser light L1.

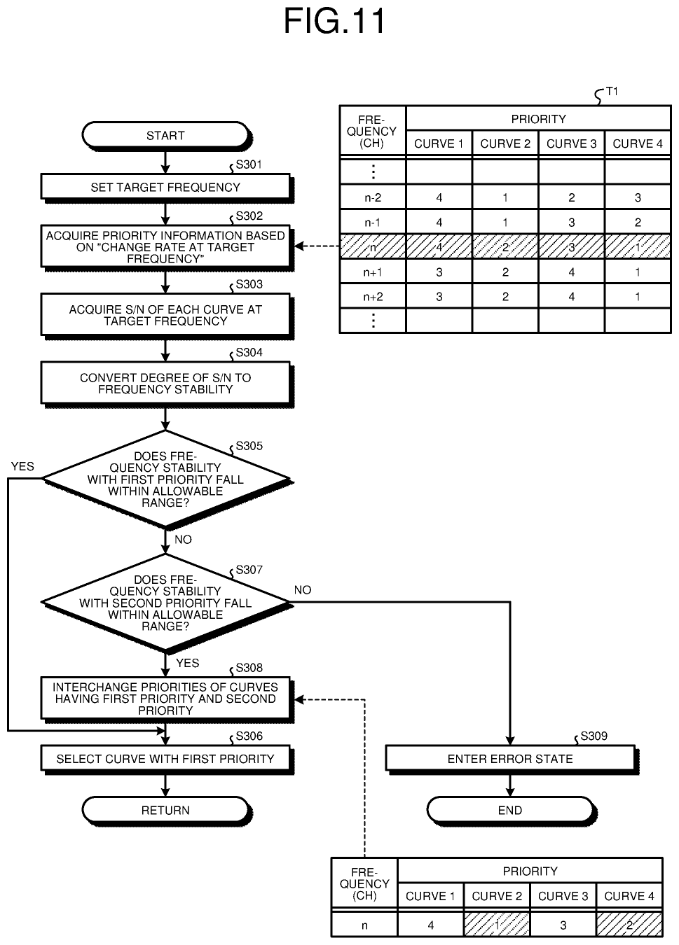

FIG. 11 is a flowchart illustrating a part of a control method performed by the laser apparatus of the fourth modification. The flowchart indicates only a part replaced with Steps S101 and S102 in the flowchart illustrated in FIG. 9. After return in FIG. 11, Steps S103 to S115 in FIG. 9 are performed in the control flow.

At Step S301, the target frequency setting unit 351 sets a target frequency as a target value of the frequency of the laser light L1.

Subsequently, at Step S302, the discrimination curve selection unit 352 acquires priority information based on a “change rate at target frequency” from the table data that is stored in the storage unit 36. Here, the table data T1 stores therein the priority information based on the “change rate at target frequency”. In the table data T1, the frequency is associated with a channel number (CH), and in this example, it is assumed that the target frequency is associated with a channel n. In this case, at the channel n, the curve 4 (the fourth frequency discrimination curve) has the first priority, and priorities are given to the curve 2 (the second frequency discrimination curve), the curve 3 (the third frequency discrimination curve), and the curve 1 (the first frequency discrimination curve) in descending order.

Then, at Step S303, the discrimination curve selection unit 352 acquires the S/N of each of the curves at the target frequency from the storage unit 36. The relative intensity of the stray light with respect to the laser light L5 or the laser light L6 may depend on the operating condition of the laser apparatus 1 or the temperature or may vary over time. To take into account the influence of the dependency or the temporal change on the S/N, it may be possible to estimate a current S/N of each of the curves by using not only the S/N that is acquired from the storage unit 36, but also the operating condition, the temperature detected by the temperature sensor 8, the environmental temperature, or the degree of deterioration, and the estimated S/N may be used at subsequent Steps. Here, specifically, the operating condition includes conditions of electric power to be supplied to the DBR heater 421, the RING heater 422, or the Phase heater 423, operating condition of the semiconductor optical amplifier 5, or the like.

Subsequently, at Step S304, the discrimination curve selection unit 352 converts the degree of the S/N to frequency stability.

Then, at Step S305, the discrimination curve selection unit 352 determines whether the frequency stability of the curve 4 that is the curve with the first priority falls within an allowable range (or is higher than a predetermined threshold). If the frequency stability falls within the allowable range (Step S305, Yes), at Step S306, the discrimination curve selection unit 352 selects the curve 4 that is the curve with the first priority and the process returns. If the frequency stability does not fall within the allowable range (Step S305, No), the flow goes to Step S307.

At Step S307, the discrimination curve selection unit 352 determines whether the frequency stability of the curve 2 with the second priority falls within the allowable range. If the frequency stability falls within the allowable range (Step S307, Yes), at Step S308, the priorities of the curves having the first priority and the second priority are interchanged with each other, and the process goes to Step S306. At Step S306, the discrimination curve selection unit 352 selects the curve 2 that is the curve with the first priority after the interchange, and the process returns.

If the frequency stability does not fall within the allowable range (Step S307, No), the flow goes to Step S309, the arithmetic unit 35 enters an error state, and the flow is terminated.

Meanwhile, a result of the priorities interchanged at Step S308 may be stored in an overwriting manner in the storage unit 36.

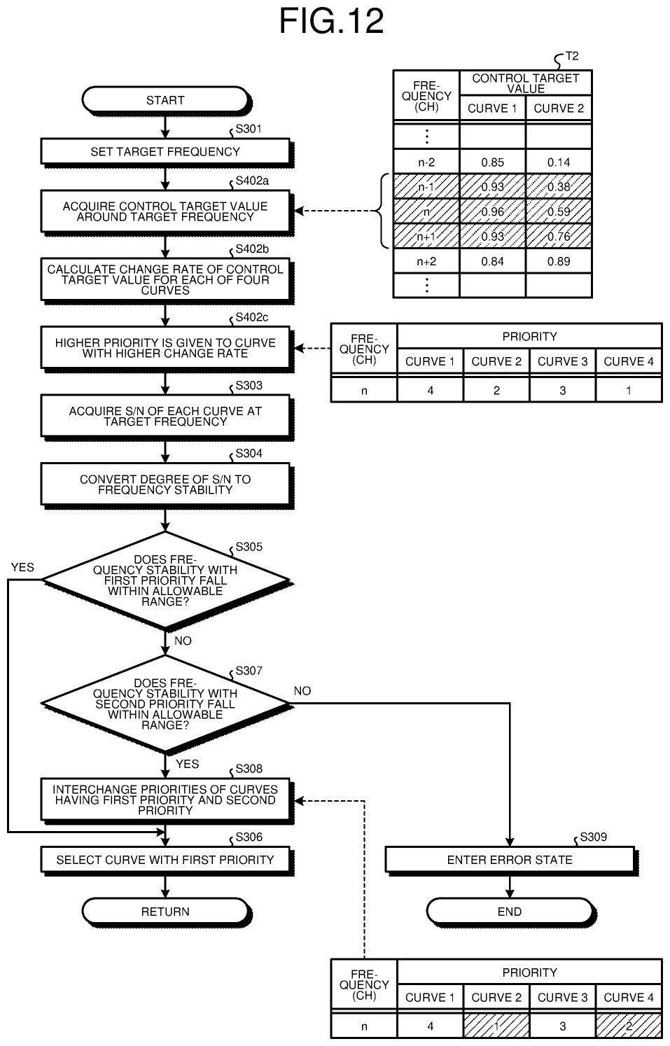

FIG. 12 is a flowchart illustrating a part of another example of the control method performed by the laser apparatus of the fourth modification. In the flowchart, Step S302 in the flowchart in FIG. 11 is replaced with Steps S402a, S402b, and S402c. Other Steps S301 and S301 to S309 are the same as those of FIG. 11, and therefore, explanation thereof will be omitted.

At Step S402a, the discrimination curve selection unit 352 acquires the control target value data of the curve 1 and the curve 2 around the target frequency (the channel n) from table data T2 that is stored in the storage unit 36. Meanwhile, the control target value data corresponds to the first ratio and the second ratio.

Subsequently, at Step S402b, the discrimination curve selection unit 352 calculates a change rate of a control target value (ratio) for each of the four curves.

Then, at Step S402c, the discrimination curve selection unit 352 gives priorities such that a higher priority is given to a curve with a higher change rate. Thereafter, Steps S303 to S309 are appropriately performed.

Another Modification of Fourth Modification

It is explained that, in the fourth modification, it is possible to estimate the current S/N of each of the curves by using not only the S/N that is acquired from the storage unit 36, but also information, such as the operating condition, the temperature detected by the temperature sensor 8, the environmental temperature, or the degree of deterioration, convert the degree of the S/N to the frequency stability, and determine the priority of the curve. In contrast, in another modification of the fourth modification, the control unit 3 may measure current frequency stability of the laser light L1, accurately evaluate the degree of the S/N, give priorities to the first to the fourth ratios, and perform selection based on the priorities. By using the measured values rather than the estimated value of the frequency stability, it is possible to give priorities and select a frequency discrimination curve based on a more appropriate S/N with respect to needed specifications. Further, it is possible to more reliably prevent or reduce reduction in the frequency stability. The current frequency stability may be acquired by monitoring a degree of variation of the electrical signal that is output from the PD 71 or the electrical signal that is output from the PD 72.

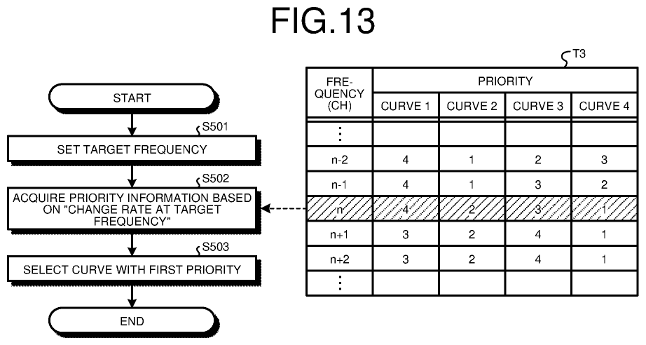

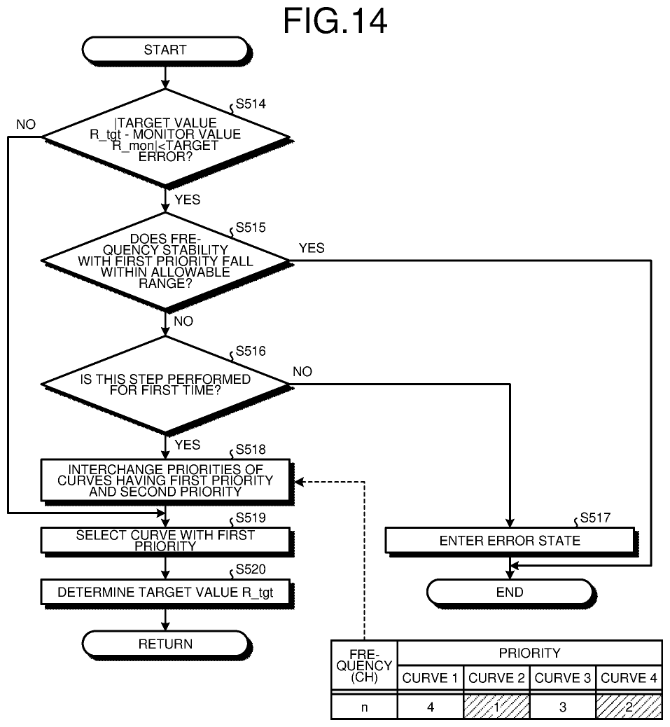

FIGS. 13 and 14 are flowcharts illustrating a part of a control method performed by a laser apparatus according to another modification of the fourth modification, and are flowcharts for giving priorities based on the change rate and the S/N. In the flowchart in FIG. 13, only a part that is replaced with Steps S101 and S102 in the flowchart illustrated in FIG. 9 is illustrated. After return in FIG. 13, Step S104, S106, S108 or S110, and Steps S111 to S113 in FIG. 9 are performed in the control flow. FIG. 14 illustrates only a part that is replaced with Steps S114 and S115 and “end” in the flowchart in FIG. 9.

First, as explanation of FIG. 13, at Step S501, the target frequency setting unit 351 sets a target frequency as a target value of the frequency of the laser light L1.

Subsequently, at Step S502, the discrimination curve selection unit 352 acquires priority information based on a “change rate at target frequency” from the table data stored in the storage unit 36. Here, table data T3 stores therein the priority information based on the “change rate at target frequency”. In the table data T3, the frequency is associated with a channel number (CH), and in this example, it is assumed that the target frequency is associated with the channel n. At this time, at the channel n, the curve 4 (the fourth frequency discrimination curve) has the first priority, and priorities are given to the curve 2 (the second frequency discrimination curve), the curve 3 (the third frequency discrimination curve), and the curve 1 (the first frequency discrimination curve) in descending order.

Then, at Step S503, the discrimination curve selection unit 352 selects the curve 4 that is the curve with the first priority and the process returns.

As the explanation of FIG. 14, at Step S514, the PID control unit 356 determines whether Ithe target value R_tgt—the monitor value R_mon| that is an absolute value of the difference falls within a target margin of error. If it is determined that the absolute value falls within the target margin of error (Step S514, Yes), the process control goes to S515. Meanwhile, if it is determined that the absolute value does not fall within the target margin of error (Step S514, No), the process control goes to Step S519 to be described later.

At Step S515, the discrimination curve selection unit 352 determines whether the frequency stability of the curve 4 that is the curve with the first priority falls within the allowable range (or is higher than the predetermined threshold). If the frequency stability falls within the allowable range (Step S515, Yes), the flow is terminated. If the frequency stability does not fall within the allowable range (Step S515, No), the flow returns to Step S516.

At Step S516, the discrimination curve selection unit 352 determines whether this step is performed for the first time. If this step is not performed for the first time (Step S516, No), the flow goes to Step S517, the arithmetic unit 35 enters an error state, and the flow is terminated.

In contrast, if this step is performed for the first time (Step S516, Yes), at Step S518, the priorities of the curves with the first priority and the second priority are interchanged with each other, and the process goes to Step S519. At Step S519, the discrimination curve selection unit 352 selects the curve 2 that is the curve with the first priority after the interchange. Subsequently, at Step S520, the target value acquisition unit 353 acquires and determines the target value R_tgt corresponding to the target frequency based on the selected curve 2. Thereafter, the flow returns to Step S106 in accordance with the selected curve 2.

According to the present disclosure, it is possible to prevent reduction in control accuracy of the frequency of the laser light.

Although the disclosure has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A laser apparatus comprising:
a laser unit including
a light source unit configured to change a frequency of laser light to be output; and
a monitor unit configured to acquire a monitor value corresponding to a frequency equivalent amount corresponding to the frequency of the laser light; and
a control unit configured to control the frequency of the laser light by supplying a control amount to the laser unit, wherein
the monitor unit at least includes:
a first frequency filter and a second frequency filter that have transmission characteristics such that transmittance periodically varies with respect to a frequency of input light and phases are shifted relative to each other;
a first detection unit configured to detect first intensity corresponding to intensity of the laser light transmitted through the first frequency filter; and
a second detection unit configured to detect second intensity corresponding to intensity of the laser light transmitted through the second frequency filter, and
the control unit is configured to
acquire a target frequency that is a control target of the frequency of the laser light,
acquire a first ratio corresponding to a ratio of the first intensity to intensity of the laser light and a second ratio corresponding to a ratio of the second intensity to the intensity of the laser light,
set, as a monitor value corresponding to the frequency of the laser light, one of the first ratio, the second ratio, a third ratio that is a sum of the first ratio and the second ratio, and a fourth ratio that is a difference between the first ratio and the second ratio,
acquire a target value corresponding to the target frequency based on one of the first to the fourth ratios, and
control the control amount such that an absolute value of a difference between the target value and the monitor value is reduced.

2. The laser apparatus according to claim 1, wherein the control unit is configured to calculate one of the first ratio and the second ratio by applying a correction coefficient to one of the first intensity, the second intensity, and the intensity of the laser light.

3. The laser apparatus according to claim 1, wherein the control unit is configured to convert the first intensity, the second intensity, and the intensity of the laser light to digital signals and calculates one of the first ratio and the second ratio by digital calculation.

4. The laser apparatus according to claim 1, wherein transmittance of each of the first frequency filter and the second frequency filter varies sinusoidally with respect to a frequency change.

5. The laser apparatus according to claim 1, wherein the control unit is configured to calculate one of the first ratio and the second ratio by converting a frequency function that represents one of the transmission characteristic of the first frequency filter and the transmission characteristic of the second frequency filter to a sine function of the frequency based on the first intensity, the second intensity, and the intensity of the laser light.

6. The laser apparatus according to claim 1, wherein the laser unit is configured to change the frequency of the laser light by using a Vernier effect.

7. The laser apparatus according to claim 1, wherein the control unit is configured to control the frequency of the laser light by supplying electric power corresponding to the control amount to the laser unit.

8. The laser apparatus according to claim 7, further comprising:
a temperature controller having a mounting surface on which the light source unit, the first frequency filter, and the second frequency filter are mounted, wherein
the light source unit, the first frequency filter, and the second frequency filter are mounted on a same mounting surface of the temperature controller.

9. The laser apparatus according to claim 1, wherein the control unit is configured to
give priorities to the first to the fourth ratios, and
select a ratio set as a monitor value corresponding to the frequency of the laser light based on a change rate of the ratio with respect to a frequency change at the target value.

10. The laser apparatus according to claim 1, wherein the control unit is configured to
give priorities to the first to the fourth ratios, and
select a ratio set as a monitor values corresponding to the frequency of the laser light based on an S/N of the ratio with respect to a frequency change at the target value.

11. The laser apparatus according to claim 1, wherein the control unit is configured to
give priorities to the first to the fourth ratios, and
select a ratio set as a monitor value corresponding to the frequency of the laser light based on a change rate and an S/N of the ratio with respect to a frequency change at the target value.

12. The laser apparatus according to claim 1, further comprising:
a temperature controller having a mounting surface on which the light source unit, the first frequency filter, and the second frequency filter are mounted, wherein
the control unit is configured to correct control temperature of the temperature controller and one of the first ratio, the second ratio, and the monitor value such that one of a lateral shift and a vertical shift of the transmission characteristics of the first frequency filter and the second frequency filter is cancelled out.

13. The laser apparatus according to claim 1, further comprising:
a temperature controller having a mounting surface on which the light source unit, the first frequency filter, and the second frequency filter are mounted; and
an environmental temperature sensor configured to detect environmental temperature of the first frequency filter and the second frequency filter, wherein
the control unit is configured to correct control temperature of the temperature controller and one of the first ratio, the second ratio, and the monitor value such that changes of the transmission characteristics of the first frequency filter and the second frequency filter due to the environmental temperature are cancelled out based on the environmental temperature detected by the environmental temperature sensor.

14. A laser apparatus control method implemented by a laser apparatus including a light source unit configured to change a frequency of laser light to be output, the laser apparatus control method comprising:
acquiring a target frequency as a control target of the frequency of the laser light;
detecting intensity of the laser light by
detecting first intensity corresponding to intensity of the laser light transmitted through a first frequency filter, the first frequency filter having a transmission characteristic such that transmittance periodically varies with respect to a frequency of input light and a phase is shifted relative to a second frequency filter that has a transmission characteristic such that transmittance periodically varies with respect to the frequency of the input light, and
detecting second intensity corresponding to intensity of the laser light transmitted through the second frequency filter;
acquiring a first ratio corresponding to a ratio of the first intensity to the intensity of the laser light and a second ratio corresponding to a ratio of the second intensity to the intensity of the laser light;
setting a monitor value corresponding to a frequency equivalent amount corresponding to the frequency of the laser light from among the first ratio, the second ratio, a third ratio that is a sum of the first ratio and the second ratio, and a fourth ratio that is a difference between the first ratio and the second ratio;
acquiring a target value corresponding to the target frequency based on one of the first to the fourth ratios; and
adjusting a control amount such that an absolute value of a difference between the target value and the monitor value is reduced.
